(19) United States
(12) Patent Application Publication
(10) Pub. No.: US 2026/0301779 A1
(43) Pub. Date: Oct. 1, 2026

(54) SEMICONDUCTOR DEVICE INCLUDING MEMORY STRUCTURE AND METHOD FOR MANUFACTURING THE SAME

(71) Applicant: TAIWAN SEMICONDUCTOR MANUFACTURING COMPANY, LTD., Hsinchu (TW)

(72) Inventors: Harry-Haklay CHUANG, Hsinchu (TW); Sheng-Chang CHEN, Hsinchu (TW); Hung Cho WANG, Hsinchu (TW); Sheng-Huang HUANG, Hsinchu (TW); Kuo-Yuan TU, Hsinchu (TW)

(73) Assignee: TAIWAN SEMICONDUCTOR MANUFACTURING COMPANY, LTD., Hsinchu (TW)

(21) Appl. No.: 19/089,797

(22) Filed: Mar. 25, 2025

(51) Int. Cl. G11C 5/08; H10B 61/00; H10N 50/01; H10N 50/10

(52) U.S. Cl. CPC G11C 5/08; H10B 61/00; H10N 50/01; H10N 50/10

(57) ABSTRACT

A method for manufacturing a semiconductor device includes: forming a metallization layer over a substrate, the metallization layer including a first dielectric layer and a metal line disposed in the first dielectric layer; forming a memory element disposed over and electrically connected to the metal line; forming a cap to laterally cover the memory element; forming a protective feature on the cap so as to cover a top surface of the memory element; forming a second dielectric layer on the protective feature and the cap opposite to the first dielectric layer; and forming a contact via to penetrate the second dielectric layer and to terminate at the protective feature, so that the contact via is electrically connected to the memory element through the protective feature.

### BACKGROUND

Semiconductor devices including memory structures (for example, dynamic random-access memories (DRAMs), static random-access memories (SRAMs), magnetic random-access memories (MRAMs), etc.) have been applied in various electrical devices, such as Internet of Things (IoT), microcontroller, etc. It is noted that, the MRAMs are regarded as next generation semiconductor memory structures due to their superior performance, such as high capacity or low energy consumption. Nevertheless, there is a continuous need to improve electrical performance of the MRAMs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor device in accordance with some embodiments.

FIGS. 2 to 12 are schematic views illustrating some intermediate stages of the method as depicted in FIG. 1 in accordance with some embodiments.

FIG. 13 is a schematic view illustrating a semiconductor device in accordance with some embodiments.

FIG. 14 is a schematic view illustrating an intermediate stage of a method for manufacturing the semiconductor device depicted in FIG. 13 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “bottom,” “top,” “lower,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

A magnetic random-access memory (MRAM) is a type of non-volatile random-access memory in which data is stored in magnetic domains. A MRAM structure includes a plurality of magnetic memory elements, each of which includes a bottom electrode, a top electrode, and a magnetic tunneling junction (MTJ) disposed between the bottom electrode and the top electrode. In some embodiments, the MRAM structure (or the magnetic memory elements) may be embedded in a metallization layer of an interconnect structure.

At present, during a process for manufacturing the interconnect structure, the MRAM structure may suffer from a current leakage (a short failure) issue caused by a tiger-tooth configuration of a contact via disposed on the MRAM structure. This tiger-tooth configuration of the contact via (i.e., the contact via is not precisely and fully formed on the top electrode of a corresponding one of the magnetic memory elements of the MRAM structure, and in particular, a portion of the contact via is formed on a sidewall of the MTJ) arises from overlay shift during formation of the contact via, and may electrically connect the bottom electrode and the top electrode of the corresponding one of the magnetic memory elements, causing current leakage and a yield loss of the MRAM structure.

In addition, in the interconnect structure, each of the magnetic memory elements may be disposed between a bottom electrode via (BEVA) and a barrier layer (made of tantalum or tantalum nitride). In this case, a high resistance may be induced between the each of the magnetic memory elements and a contact via (disposed on the barrier layer) because the barrier layer may be easily oxidized before formation of the contact via.

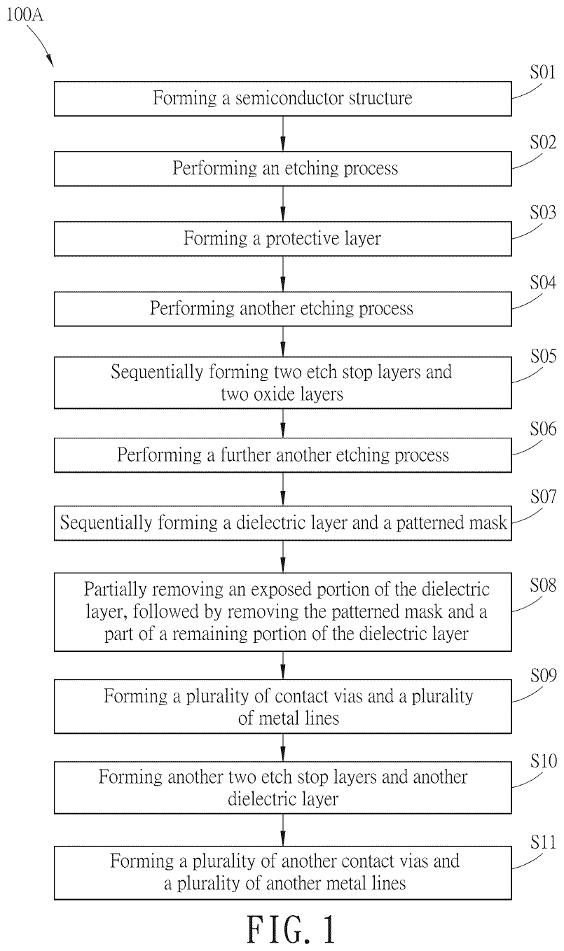

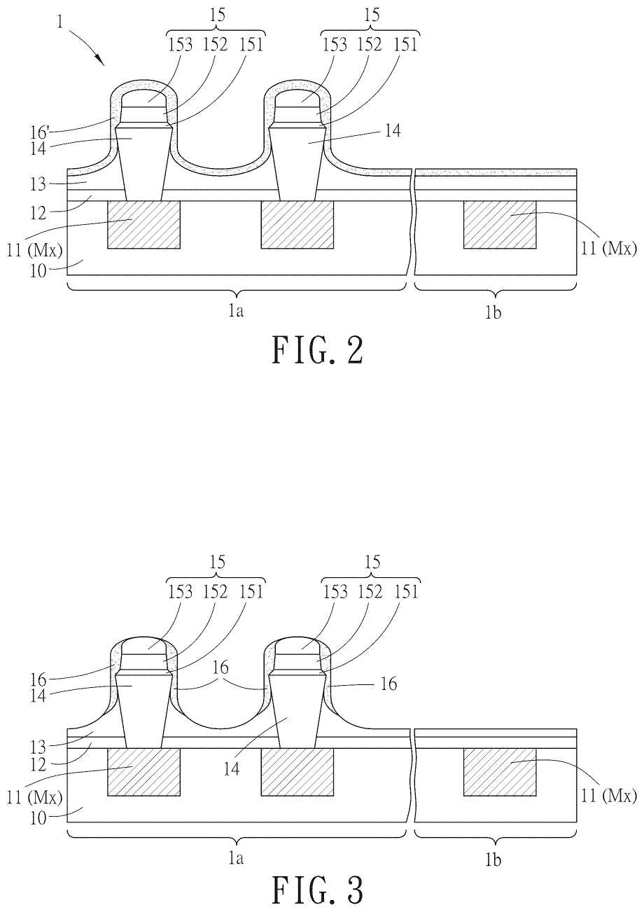

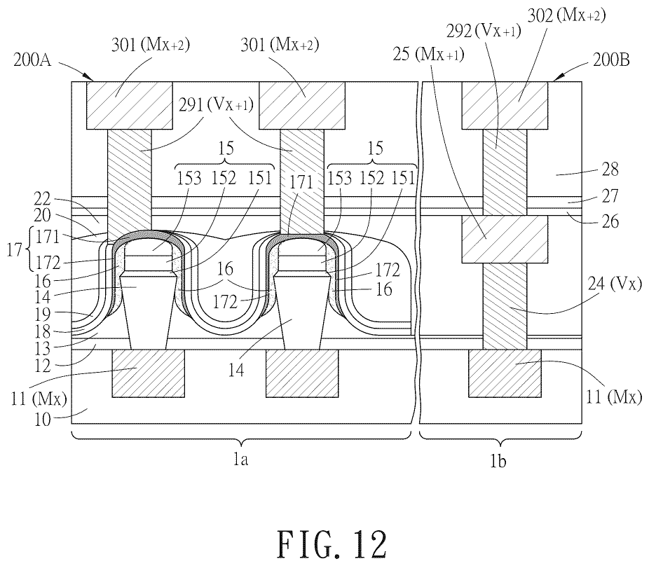

The present disclosure is directed to a semiconductor device and a method for manufacturing the same. FIG. 1 is a flow diagram illustrating a method 100A for manufacturing a first semiconductor device 200A and a second semiconductor device 200B shown in FIG. 12 in accordance with some embodiments. FIGS. 2 to 11 illustrate schematic views of some intermediate stages of the method 100A. Some portions in FIGS. 2 to 11 may be omitted for the sake of brevity. Additional steps can be provided before, after or during the method 100A, and some of the steps described herein may be replaced by other steps or be eliminated.

Referring to FIG. 1 and the example illustrated in FIG. 2, the method 100A begins at step S01, where a semiconductor structure 1 is formed. In some embodiments, the semiconductor structure 1 is formed on a topmost dielectric layer of an interconnect structure (not shown) disposed on a semiconductor substrate (not shown).

The semiconductor structure 1 includes a dielectric layer 10, a plurality of metal lines 11 (a metallization layer (Mₓ)), a silicide-blocking layer (SBL) 12, a silicon-rich oxide layer 13, a plurality of bottom electrode vias (BEVAs) 14, a plurality of magnetic memory elements 15, and a cap layer 16′.

The dielectric layer 10 is formed on the topmost dielectric layer of the interconnect structure. In some embodiments, the dielectric layer 10 includes or is made of, for example, but not limited to, silicon oxide, silicon nitride, silicon carbide, silicon oxycarbide, silicon oxynitride, silicon carbonitride, silicon oxycarbonitride, undoped silicate glass (USG), phosphosilicate glass (PSG), borosilicate glass (BSG), boron-doped phosphosilicate glass (BPSG), fluorine-doped silicate glass (FSG), low-dielectric constant (k) dielectric materials, extreme low-k dielectric materials, or combinations thereof. In some alternative embodiments, the dielectric layer 10 includes or is made of, for example, but not limited to, polyimide, epoxy resin, acrylic resin, phenol resin, benzocyclobutene (BCB), polybenzooxazole (PBO), other suitable polymer-based dielectric materials, or combinations thereof. Other suitable materials for the dielectric layer 10 are within the contemplated scope of the present disclosure. In some embodiments, the dielectric layer 10 may include a memory region 1a and a logic region 1b.

The metal lines 11 are disposed in the dielectric layer 10 and are spaced apart from one another. In some embodiments, the metal lines 11 include or are made of, for example, but not limited to, copper, aluminum, tungsten, or combinations thereof. Other suitable materials for the metal lines 11 are within the contemplated scope of the present disclosure.

The SBL 12 is disposed on the dielectric layer 10 and the metal lines 11. In some embodiments, the SBL 12 includes or is made of a dielectric material, for example, but not limited to, silicon oxide or silicon nitride. Other suitable materials for the SBL 12 are within the contemplated scope of the present disclosure. In some embodiments, the SBL 12 has a thickness ranging from about 62.5 Å to about 187.5 Å.

The silicon-rich oxide layer 13 is disposed on the SBL 12 opposite to the dielectric layer 10. In some embodiments, the silicon-rich oxide layer 13 includes or is made of silicon oxide. In some embodiments, the silicon-rich oxide layer 13 has a thickness ranging from about 115 Å to about 345 Å.

The BEVAs 14 are disposed in the SBL 12 and the silicon-rich oxide layer 13 over the memory region 1a, are spaced apart from each other, and are electrically connected to the metal lines 11, respectively. In some embodiments, the BEVAs 14 include or are made of, for example, but not limited to, titanium nitride, tantalum, tantalum nitride, or combinations thereof. Other suitable materials for the BEVAs 14 are within the contemplated scope of the present disclosure. In some embodiments, each of the BEVAs 14 may have a cross-section of an inverted trapezoid shape. Other geometrical shapes for each of the BEVAs 14 are within the contemplated scope of the present disclosure.

The magnetic memory elements 15 are disposed on the BEVAs 14, respectively. Each of the magnetic memory elements 15 includes a bottom electrode 151, a magnetic tunneling junction (MTJ) 152, and a top electrode 153.

The bottom electrode 151 of each of the magnetic memory elements 15 is disposed on a corresponding one of the BEVAs 14. In some embodiments, the bottom electrode 151 includes or is made of, for example, but not limited to, titanium nitride, tungsten, tantalum, tantalum nitride, or combinations thereof. Other suitable materials for the bottom electrode 151 are within the contemplated scope of the present disclosure.

The MTJ 152 is disposed on the bottom electrode 151. In some embodiments, the MTJ 152 includes at least one ferromagnetic layer, which may include or be made of a ferromagnetic material, for example, but not limited to, a metal (e.g., cobalt, nickel, iron, etc.), a metal alloy (e.g., cobalt iron boron, iron boron, cobalt iron, iron platinum, iron palladium, cobalt nickel, chromium nickel, terbium iron cobalt, etc.) or a combination thereof. Other suitable ferromagnetic materials for the MTJ 152 are within the contemplated scope of the present disclosure. In some embodiments, the MTJ 152 may be formed as a multilayered structure, which includes the at least one ferromagnetic layer.

The top electrode 153 is disposed on the MTJ 152 opposite to the bottom electrode 151. In some embodiments, the top electrode 153 includes or is made of, for example, but not limited to, titanium nitride, tungsten, tantalum, tantalum nitride, or combinations thereof. Other suitable materials for the top electrode 153 are within the contemplated scope of the present disclosure. In some embodiments, the top electrode 153 has a curved top surface.

The cap layer 16′ covers the silicon-rich oxide layer 13, the BEVAs 14, and the magnetic memory elements 15. In some embodiments, the cap layer 16′ includes or is made of, for example, but not limited to, silicon nitride. Other suitable materials for the cap layer 16′ are within the contemplated scope of the present disclosure. In some embodiments, the cap layer 16′ has a thickness ranging from about 130 Å to about 390 Å.

Referring to FIG. 1 and the example illustrated in FIG. 3, the method 100A then proceeds to step S02, where horizontal portions of the cap layer 16′ are removed. Step S02 is performed by a suitable etching process, for example, but not limited to, an anisotropic dry etching process. Other suitable etching processes are within the contemplated scope of the present disclosure. After this step, the cap layer 16′ is formed into a plurality of caps 16 (i.e., vertical portions of the cap layer 16′), and a top surface of each of the magnetic memory elements 15 (i.e., the curved top surface of the top electrode 153) is exposed. Each of the caps 16 surrounds and covers a sidewall of each of the magnetic memory elements 15 and a portion of a sidewall of each of the BEVAs 14. In addition, each of the caps 16 also covers a portion of the silicon-rich oxide layer 13. In some embodiments, the silicon-rich oxide layer 13 may be slightly removed after this step.

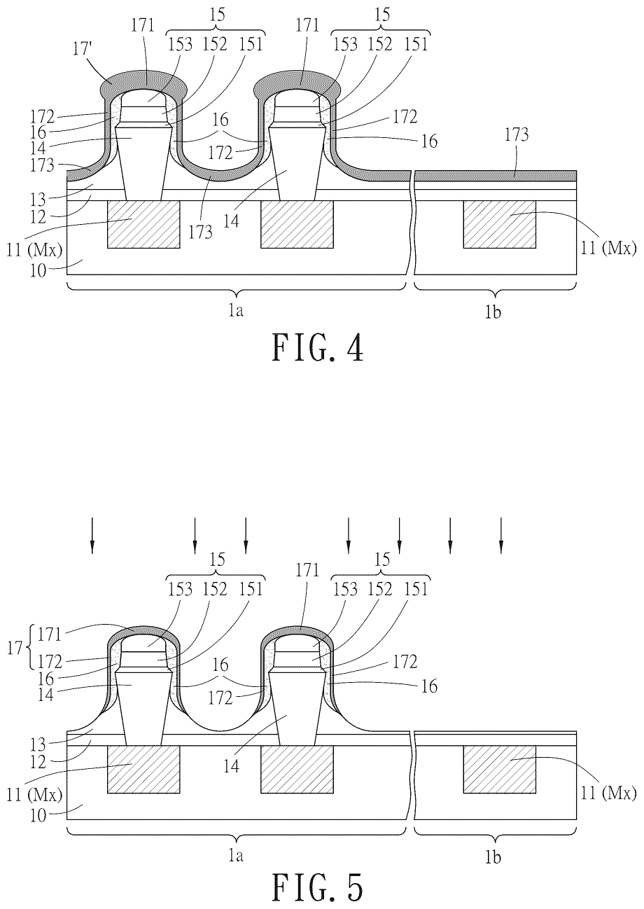

Referring to FIG. 1 and the example illustrated in FIG. 4, the method 100A then proceeds to step S03, where a protective layer 17′ is formed on the structure shown in FIG. 3. In some embodiments, the protective layer 17′ includes or is made of, for example, but not limited to, metal (e.g., tungsten, cobalt, or titanium), metal nitride (e.g., titanium nitride), metal silicide (e.g., titanium silicide), or combinations thereof. Other suitable materials for forming the protective layer 17′ are within the contemplated scope of the present disclosure. In some embodiments, the protective layer 17′ is formed by a suitable deposition process, for example, but not limited to, chemical vapor deposition (CVD) or physical vapor deposition (PVD). Other suitable deposition processes for forming the protective layer 17′ are within the contemplated scope of the present disclosure. In some embodiments, the protective layer 17′ includes a plurality of upper protective portions 171, a plurality of intermediate protective portions 172, and a plurality of lower protective portions 173. Each of the upper protective portions 171 covers the top surface of a corresponding one of the magnetic memory elements 15 and a top surface of a corresponding one of the caps 16. The lower protective portions 173 cover portions of the silicon-rich oxide layer 13. Each of the intermediate protective portions 172 connects a corresponding one of the upper protective portions 171 and a corresponding one of the lower protective portions 173, and laterally covers a corresponding one of the caps 16. In some embodiments, the protective layer 17′ has a thickness ranging from about 100 Å to about 500 Å. In some embodiments, a thickness of each of the upper protective portions 171 is greater than that of each of the lower protective portions 173, and the thickness of each of the lower protective portions 173 is greater than that of each of the intermediate protective portions 172.

Referring to FIG. 1 and the example illustrated in FIG. 5, the method 100A then proceeds to step S04, where the lower protective portions 173, and a portion of each of the upper protective portions 171 and the intermediate protective portions 172 are removed. Step S04 is performed by a suitable etching process, for example, but not limited to, an anisotropic dry etching process. Other suitable etching processes are within the contemplated scope of the present disclosure. In some embodiments, a plasma power used in the anisotropic dry etching process ranges from about 100 watt (W) to about 1000 W. If the plasma power is greater than 1000 W, the upper protective portions 171 may be fully removed or other elements (e.g., the magnetic memory elements 15) may be damaged. After this step, the thickness of each of the upper protective portions 171 ranges from about 50 Å to about 450 Å. If the thickness of each of the upper protective portions 171 is lower than 50 Å, the upper protective portions 171 may be removed during subsequent formation of a plurality of contact vias 291, 292 (with reference to FIG. 12), which may induce formation of a tiger-tooth configuration of the contact vias 291 and a current leakage of the magnetic memory elements 15. If the thickness of each of the upper protective portions 171 is greater than 450 Å, a size of a corresponding one of the contact vias 291 or other elements formed in a subsequent step may be adversely affected. In some embodiments, a ratio of the thickness of each of the upper protective portions 171 to a thickness of the bottom electrode 151 of a corresponding one of the magnetic memory elements 15 ranges from about 33% to about 250%. In some embodiments, a ratio of a surface area of each of the upper protective portions 171 to a surface area of a top surface of a corresponding one of the magnetic memory elements 15 disposed below the each of the upper protective portions 171 ranges from about 100% to about 250%, so as to ensure each of the upper protective portions 171 fully covers the corresponding one of the magnetic memory elements 15. It is noted that, in this step, if the lower protective portions 173 of the protective layer 17′ are not fully removed, the magnetic memory elements 15 may be electrically connected to each other, causing a bridge issue.

Each of the upper protective portions 171 and a corresponding one of the intermediate protective portions 172 remaining after step S04 may be collectively referred to a protective feature 17. In other words, a plurality of the protective features 17 are formed after step S04.

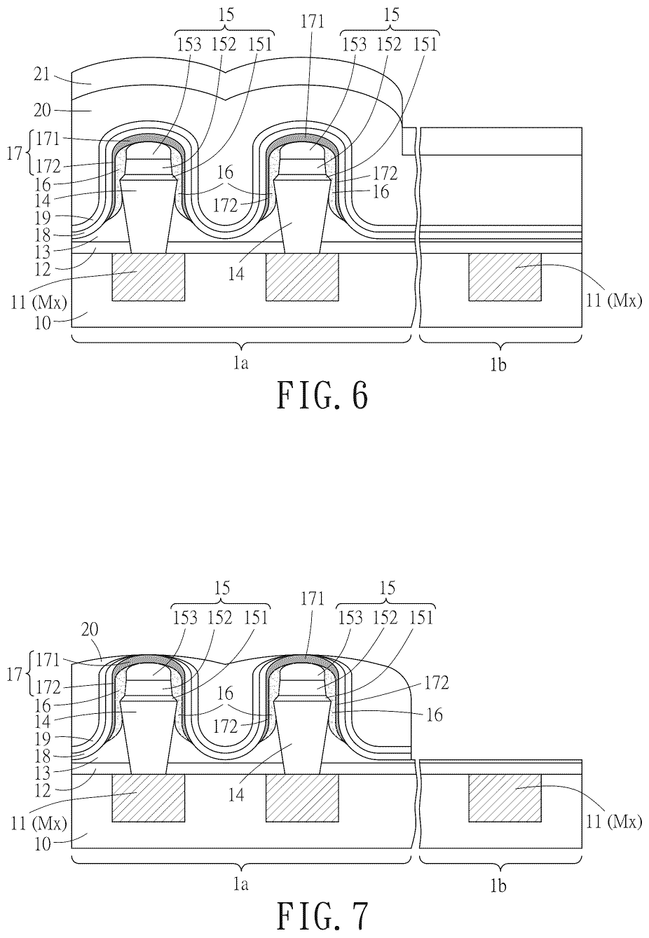

Referring to FIG. 1 and the example illustrated in FIG. 6, the method 100A then proceeds to step S05, where an etch stop layer 18, an etch stop layer 19, an oxide layer 20, and an oxide layer 21 are sequentially formed on the structure shown in FIG. 5.

In this step, the etch stop layer 18 is firstly formed on the structure shown in FIG. 5. In some embodiments, the etch stop layer 18 includes or is made of, for example, but not limited to, silicon oxycarbide. Other suitable materials for forming the etch stop layer 18 are within the contemplated scope of the present disclosure. In some embodiments, the etch stop layer 18 is conformally formed on the structure shown in FIG. 5 by a suitable deposition process, for example, but not limited to, CVD or atomic layer deposition (ALD). Other suitable deposition processes for forming the etch stop layer 18 are within the contemplated scope of the present disclosure. In some embodiments, the etch stop layer 18 has a thickness ranging from about 75 Å to about 225 Å.

Thereafter, the etch stop layer 19 is conformally formed on the etch stop layer 18. In some embodiments, the etch stop layer 19 includes or is made of, for example, but not limited to, silicon oxynitride. Other suitable materials for forming the etch stop layer 19 are within the contemplated scope of the present disclosure. In some embodiments, the etch stop layer 19 is formed by a suitable deposition process, for example, but not limited to, CVD or ALD. Other suitable deposition processes for forming the etch stop layer 19 are within the contemplated scope of the present disclosure. In some embodiments, the etch stop layer 19 has a thickness ranging from about 100 Å to about 300 Å.

Then, the oxide layer 20 is formed on the etch stop layer 19 opposite to the etch stop layer 18. In some embodiments, the oxide layer 20 includes or is made of an oxide-based material, for example, but not limited to, silicon oxide. Other suitable oxide-based materials for forming the oxide layer 20 are within the contemplated scope of the present disclosure. In some embodiments, the oxide layer 20 is formed by a suitable deposition process, for example, but not limited to, plasma-enhanced ALD. Other suitable deposition processes for forming the oxide layer 20 are within the contemplated scope of the present disclosure. In some embodiments, the oxide layer 20 has a thickness ranging from about 350 Å to about 1050 Å.

After that, the oxide layer 21 is formed on the oxide layer 20 opposite to the etch stop layer 19. In some embodiments, the oxide layer 21 includes or is made of an oxide-based material, for example, but not limited to, tetraethoxysilane (TEOS). Other suitable oxide-based materials for forming the oxide layer 21 are within the contemplated scope of the present disclosure. In some embodiments, the oxide layer 21 is formed by a suitable deposition process, for example, but not limited to, CVD. Other suitable deposition processes for forming the oxide layer 21 are within the contemplated scope of the present disclosure. In some embodiments, the oxide layer 21 has a thickness ranging from about 150 Å to about 450 Å.

Referring to FIG. 1 and the example illustrated in FIG. 7, the method 100A then proceeds to step S06, where the oxide layer 21, a portion of the oxide layer 20, a portion of the etch stop layer 19, and a portion of the etch stop layer 18 are removed. Step S06 is performed by a suitable etching process, for example, but not limited to, a dry etching process. Other suitable etching processes are within the contemplated scope of the present disclosure. It is noted that a remaining portion of each of the oxide layer 20, the etch stop layer 19, and the etch stop layer 18 are mainly located at the memory region 1a.

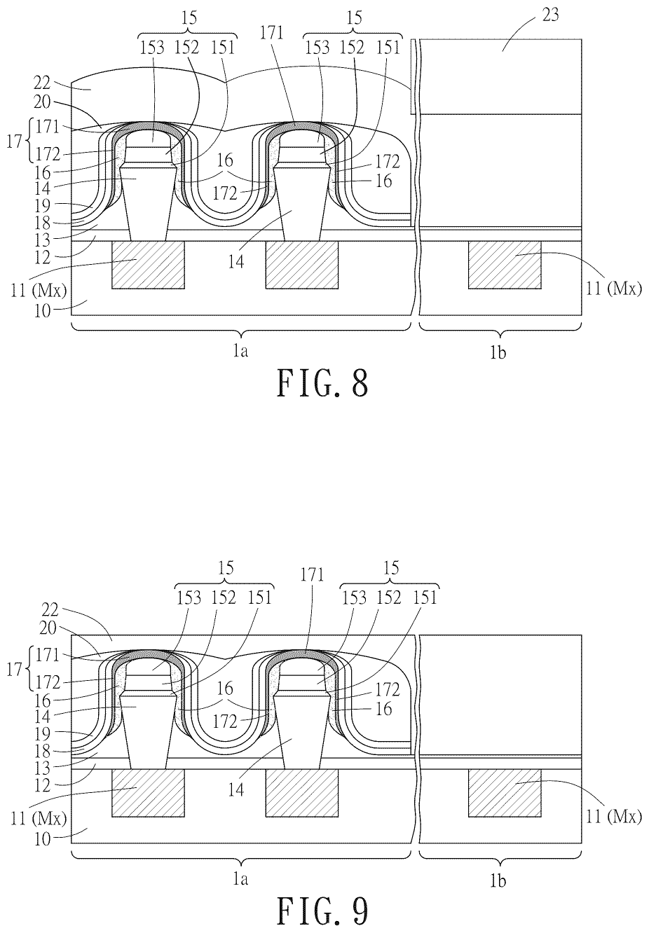

Referring to FIG. 1 and the example illustrated in FIG. 8, the method 100A then proceeds to step S07, where a dielectric layer 22 and a patterned mask 23 are sequentially formed on the structure shown in FIG. 7.

In this step, the dielectric layer 22 is firstly formed on the structure shown in FIG. 7. The material for forming the dielectric layer 22 is the same as or similar to that for forming the dielectric layer 10, and thus details thereof are omitted for the sake of brevity. In some embodiments, the dielectric layer 22 is formed by a suitable deposition process, for example, but not limited to, CVD. Other suitable deposition processes for forming the dielectric layer 22 are within the contemplated scope of the present disclosure. In some embodiments, a dielectric constant of the dielectric layer 22 is different from that of the dielectric layer 10.

The patterned mask 23 is formed on the structure obtained after formation of the dielectric layer 22. In some embodiments, the patterned mask 23 includes or is made of, for example, but not limited to, a photoresist material. Other suitable materials for forming the patterned mask 23 are within the contemplated scope of the present disclosure. In some embodiments, the patterned mask 23 is formed by coating a photoresist material layer (not shown) on the structure obtained after the formation of the dielectric layer 22, soft-baking the photoresist material layer, exposing the photoresist material layer through a photomask (not shown), post-exposure baking the photoresist material layer, and developing the photoresist material layer, followed by hard-baking the photoresist material layer to thereby form the patterned mask 23. In some embodiments, a portion of the dielectric layer 22 is exposed from the patterned mask 23.

Referring to FIG. 1 and the example illustrated in FIG. 9, the method 100A then proceeds to step S08, where an exposed portion of the dielectric layer 22 is partially removed, followed by removing the patterned mask 23 and a part of a remaining portion of the dielectric layer 22.

In this step, the exposed portion of the dielectric layer 22 is partially removed by a suitable etching process, for example, but not limited to, a dry etching process. Other suitable etching processes are within the contemplated scope of the present disclosure.

Thereafter, the patterned mask 23 and the part of the remaining portion of the dielectric layer 22 are removed. In some embodiments, the patterned mask 23 is removed by a suitable removal process, for example, but not limited to, an ashing process. Other suitable removal processes for removing the patterned mask 23 are within the contemplated scope of the present disclosure. In some embodiments, the part of the remaining portion of the dielectric layer 22 is removed by a suitable planarization process, for example, but not limited to, chemical mechanical polishing (CMP). Other suitable removal processes for removing the patterned mask 23 and other planarization processes for removing the part of the remaining portion of the dielectric layer 22 are within the contemplated scope of the present disclosure. In some embodiments, the patterned mask 23 and the part of the remaining portion of the dielectric layer 22 may be removed together by a suitable planarization process.

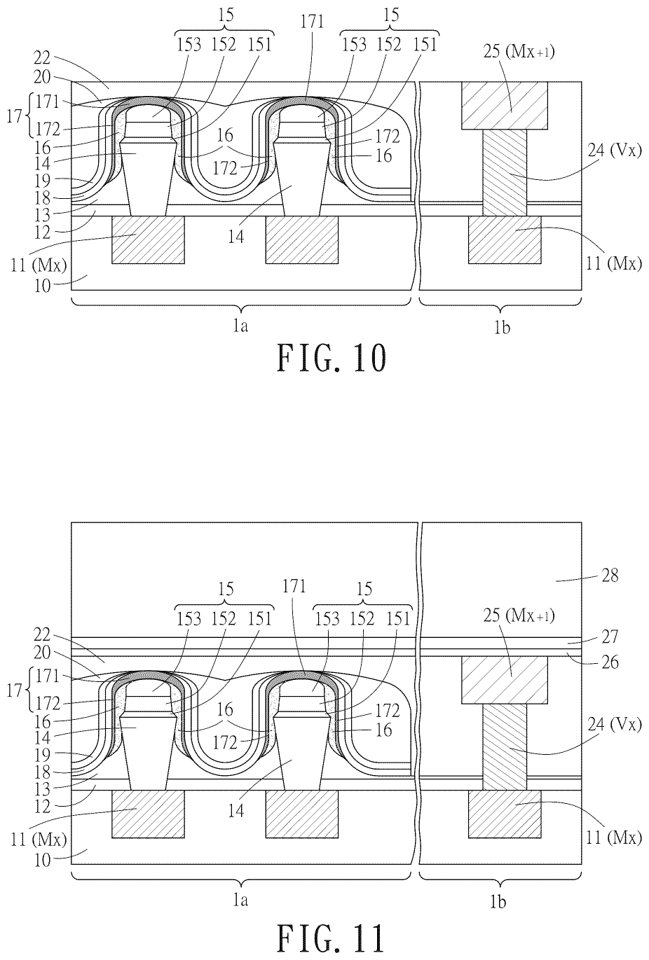

Referring to FIG. 1 and the example illustrated in FIG. 10, the method 100A then proceeds to step S09, where a plurality of contact vias 24 (metal vias (Vₓ)) and a plurality of metal lines 25 (a metallization layer (Mₓ₊₁)) are formed. One of the contact vias 24 and one of the metal lines 25 are shown in FIG. 10.

In some embodiments, the contact vias 24 and the metal lines 25 may be formed at the same time using a dual damascene process. A plurality of openings (not shown) are firstly formed on the structure shown in FIG. 9 over the logic region 1b through a patterned mask while the structure over the memory region 1a is masked by the patterned mask. Each of the openings includes a lower portion (a via opening) and an upper portion (a trench) in spatial communication with the lower portion. The upper portion of each of the openings extends into the dielectric layer 22. The lower portion of each of the openings extends downwardly from the upper portion in the dielectric layer 22, and through the silicon-rich oxide layer 13 and the SBL 12. In some embodiments, the openings are formed by a photolithography process (including an etching process) conducted on the structure shown in FIG. 9 over the logic region 1b. In some embodiments, a size of the upper portion is larger than that of the lower portion.

Thereafter, a conductive material layer (not shown) is formed to fill the openings. In some embodiments, the conductive material layer includes or is made of, for example, but not limited to, copper, aluminum, tungsten, or combinations thereof. Other suitable conductive materials for forming the conductive material layer are within the contemplated scope of the present disclosure. In some embodiments, the conductive material layer is formed by a suitable process, for example, but not limited to, CVD or electroplating. Other suitable processes for forming the conductive material layer are within the contemplated scope of the present disclosure.

Then, an excess portion of the conductive material layer over the dielectric layer 22 is removed by a suitable planarization process (e.g., CMP), thereby obtaining the contact vias 24 (the metal vias (Vx)) and the metal lines 25 (the metallization layer (Mₓ₊₁)), which are formed only in the logic region 1b. In other words, the contact vias 24 (the metal vias (Vx)) and the metal lines 25 (the metallization layer (Mₓ₊₁)) are not formed in the memory region 1a.

In some embodiments, the contact vias 24 and the metal lines 25 may be formed separately and sequentially using two single damascene processes.

Referring to FIG. 1 and the example illustrated in FIG. 11, the method 100A then proceeds to step S10, where an etch stop layer 26, an etch stop layer 27, and a dielectric layer 28 are sequentially formed on the structure shown in FIG. 10.

In this step, the etch stop layer 26 is firstly formed on the structure shown in FIG. 10. In some embodiments, the etch stop layer 26 includes or is made of, for example, but not limited to, silicon carbide. Other suitable materials for forming the etch stop layer 26 are within the contemplated scope of the present disclosure. In some embodiments, the etch stop layer 26 is formed by a suitable deposition process, for example, but not limited to, CVD. Other suitable deposition processes for forming the etch stop layer 26 are within the contemplated scope of the present disclosure.

Thereafter, the etch stop layer 27 is formed on the etch stop layer 26 opposite to the dielectric layer 22. In some embodiments, the etch stop layer 27 includes or is made of, for example, but not limited to, TEOS. Other suitable materials for forming the etch stop layer 27 are within the contemplated scope of the present disclosure. In some embodiments, the etch stop layer 27 is formed by a suitable deposition process, for example, but not limited to, CVD. Other suitable deposition processes for forming the etch stop layer 27 are within the contemplated scope of the present disclosure.

Then, the dielectric layer 28 is formed on the etch stop layer 27 opposite to the etch stop layer 26. The material and process for forming the dielectric layer 28 is the same as or similar to those for forming the dielectric layer 10 or the dielectric layer 22, and thus details thereof are omitted for the sake of brevity. In some embodiments, a dielectric constant of the dielectric layer 28 is different from that of each of the dielectric layer 22 and the dielectric layer 10.

Referring to FIG. 1 and the example illustrated in FIG. 12, the method 100A then proceeds to step S11, where the contact vias 291, 292 (metal vias (Vₓ₊₁)) and a plurality of metal lines 301, 302 (a metallization layer (Mₓ₊₂)) are formed. The material and process for forming each of the contact vias 291, 292, and the metal lines 301, 302 are the same as or similar to those for forming each of the contact vias 24 and the metal lines 25, and thus details thereof are omitted for the sake of brevity. The metal lines 301, 302 are disposed in the dielectric layer 28, and a top surface of each of the metal lines 301, 302 is exposed from the dielectric layer 28. Each of the contact vias 291 is formed in the dielectric layer 28, penetrates the etch stop layers 26, 27, and is disposed between a corresponding one of the upper protective portions 171 and a corresponding one of the metal lines 301 over the memory region 1a. Each of the contact vias 292 is formed in the dielectric layer 28, penetrates the etch stop layers 26, 27, and is disposed between a corresponding one of the metal lines 302 and a corresponding one of the metal lines 25 over the logic region 1b.

After step S11, the first semiconductor device 200A and the second semiconductor device 200B are obtained. In the first semiconductor device 200A, since the upper protective portions 171 respectively cover the magnetic memory elements 15, each of the contact vias 291 can be fully disposed on a corresponding one of the upper protective portions 171, even though when one of the contact vias 291 is misaligned with a corresponding one of the magnetic memory elements 15 in a landing process, as illustrated by the left one of the contact vias 291 (see FIG. 12). Therefore, each of the contact vias 291 can avoid covering a sidewall of a corresponding one of the magnetic memory elements 15, and a current leakage (a short failure) of the corresponding one of the magnetic memory elements 15 (i.e., the bottom electrode 151 and the top electrode 153 being electrically connected to each other) can be prevented.

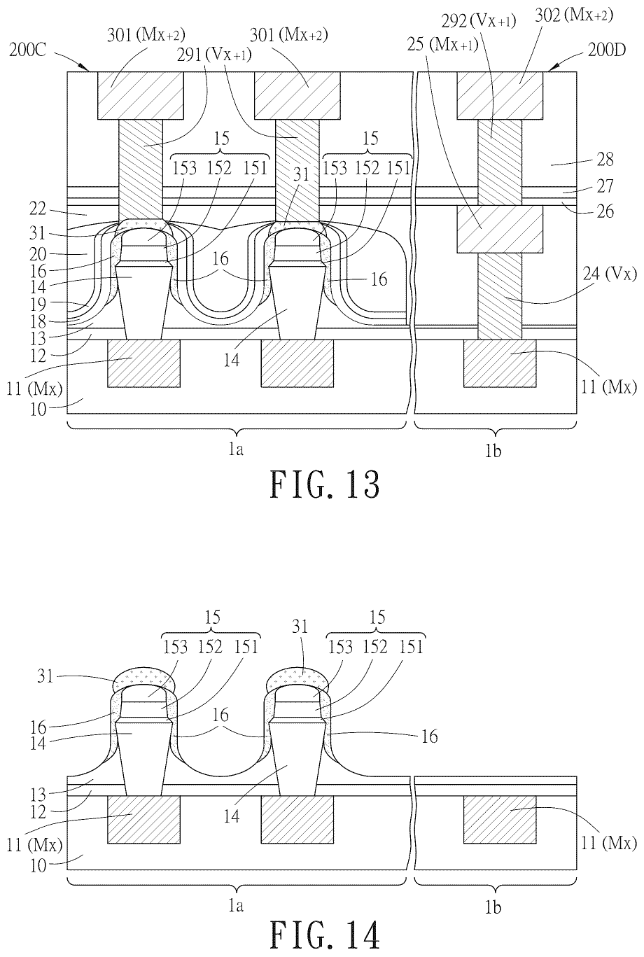

FIG. 13 illustrates a third semiconductor device 200C and a fourth semiconductor device 200D in accordance with some embodiments. A structure of the third semiconductor device 200C is generally similar to that of the first semiconductor device 200A, except that protective features 31 of the third semiconductor device 200C are different from the protective features 17 of the first semiconductor device 200A. A structure of the fourth semiconductor device 200D is the same as that of the second semiconductor device 200B. A method for manufacturing the third semiconductor device 200C and the fourth semiconductor device 200D is generally similar to the method 100A except for steps S3 and S4. FIG. 14 illustrates a schematic view of an intermediate stage of the method for manufacturing the third semiconductor device 200C and the fourth semiconductor device 200D.

In the third semiconductor device 200C, each of the protective features 31 is disposed between a corresponding one of the magnetic memory elements 15 and a corresponding one of the contact vias 291. In some embodiments, each of the protective features 31 includes or is made of, for example, but not limited to, metal (e.g., tungsten, cobalt, or titanium), metal nitride (e.g., titanium nitride), metal silicide (e.g., titanium silicide), or combinations thereof. Other suitable materials for forming the protective features 31 are within the contemplated scope of the present disclosure.

After step S2 of the method 100A and before step S5 of the method 100A, each of the protective features 31 is selectively formed on a corresponding one of the magnetic memory elements 15 using a suitable precursor or suitable precursors. In some embodiments, the precursor is formed on the corresponding one of the magnetic memory elements 15 before formation of the each of the protective features 31. In some embodiments, each of the protective features 31 is formed by a suitable selective deposition process, for example, but not limited to, selective CVD. Other suitable selective deposition processes for forming each of the protective features 31 are within the contemplated scope of the present disclosure. When the protective features 31 are made of tungsten, the protective features 31 are formed using a tungsten-containing precursor (e.g., commercial tungsten, tungsten trioxide, etc.). When the protective features 31 are made of cobalt, the protective features 31 are formed using a cobalt-containing precursor (e.g., cobalt acetate, cobalt nitrate, etc.). When the protective features 31 are made of titanium, the protective features 31 are formed using a titanium-containing precursor (e.g., tetrakis(dimethylamino)titanium (TDMAT), titanium tetrachloride, etc.). When the protective features 31 are made of titanium nitride, the protective features 31 are formed using the titanium-containing precursor (e.g., tetrakis(dimethylamino)titanium (TDMAT), titanium tetrachloride, etc.) and a nitrogen-containing precursor (e.g., ammonia, etc.). When the protective features 31 are made of titanium silicide, the protective features 31 are formed using a titanium-containing precursor (e.g., titanium hydride, titanium dioxide, etc.) and a silicon-containing precursor (e.g., silane, etc.). In some embodiments, each of the protective features 31 has a thickness ranging from about 50 Å to about 500 Å.

In some embodiments, each of the protective features 31 has a curved top surface and a curved bottom surface connecting to the curved top surface. In some embodiments, a thickness of a center portion of each of the protective features 31 is greater than that of a side portion of the each of the protective features 31. In some embodiments, the side portion of each of the protective features 31 partially covers the top surface of a corresponding one of the caps 16.

In some embodiments, each of the protective features 31 may be partially removed during formation of the contact vias 291 (step S11 of the method 100A).

In this disclosure, a protective feature is formed to cover a magnetic memory element of a magnetic random-access memory before formation of a contact via that is to be electrically connected to the magnetic memory element. Therefore, the contact via, after being formed, can be electrically connected to the magnetic memory element through the protective feature, and can be fully in contact with the protective feature without being in contact with the magnetic memory element, which is advantageous for preventing a current leakage (a short failure) of the magnetic memory element caused by an electrical connection between a bottom electrode and a top electrode of the magnetic memory element, so that a yield of the magnetic random-access memory can be enhanced. The protective feature is formed by forming a protective layer (e.g., made of tungsten, cobalt, titanium, titanium nitride, or titanium silicide) on the magnetic memory element, followed by etching back an excess portion of the protective layer. Alternatively, the protective feature can be selectively formed on the magnetic memory element using a suitable precursor or suitable precursors. In addition, a high resistance issue between the magnetic memory element and the contact via can be avoided.

In accordance with some embodiments of the present disclosure, a method for manufacturing a semiconductor device includes: forming a metallization layer over a substrate, the metallization layer including a first dielectric layer and a metal line disposed in the first dielectric layer; forming a memory element disposed over and electrically connected to the metal line; forming a cap to laterally cover the memory element; forming a protective feature on the cap so as to cover a top surface of the memory element; forming a second dielectric layer on the protective feature and the cap opposite to the first dielectric layer; and forming a contact via to penetrate the second dielectric layer and to terminate at the protective feature, so that the contact via is electrically connected to the memory element through the protective feature.

In accordance with some embodiments of the present disclosure, the method for manufacturing the semiconductor device further includes, after formation of the metallization layer and before formation of the memory element, forming a silicon-rich oxide layer on the first dielectric layer and the metal line, and forming a bottom electrode via to penetrate the silicon-rich oxide layer and to terminate at the metal line. The cap is formed on the silicon-rich oxide layer, and laterally covers a portion of a sidewall of the bottom electrode via exposed from the silicon-rich oxide layer.

In accordance with some embodiments of the present disclosure, formation of the cap includes: forming a cap layer to cover the silicon-rich oxide layer, the portion of the sidewall of the bottom electrode via, and the memory element, the cap layer including a plurality of horizontal portions and a plurality of vertical portions, the plurality of horizontal portions being formed on the silicon-rich oxide layer and the top surface of the memory element, each of the plurality of vertical portions connecting one of the plurality of horizontal portions disposed on the top surface of the memory element and an adjacent one of the plurality of horizontal portions aside the memory element, and being formed to cover the portion of the sidewall of the bottom electrode via and a sidewall of the memory element; and removing the plurality of horizontal portions so as to expose the top surface of the memory element and portions of the silicon-rich oxide layer.

In accordance with some embodiments of the present disclosure, the protective feature includes an upper protective portion and an intermediate protective portion connected to the upper protective portion, and formation of the protective feature includes: forming a protective layer including the upper protective portion, the intermediate protective portion, and a lower protective portion, the upper protective portion covering the top surface of the memory element and a top surface of the cap, the lower protective portion covering the portions of the silicon-rich oxide layer, the intermediate protective portion being connected to the upper protective portion and the lower protective portion, and laterally covering the cap; and removing the lower protective portion so as to expose the portions of the silicon-rich oxide layer.

In accordance with some embodiments of the present disclosure, the protective layer is formed by one of chemical vapor deposition and physical vapor deposition.

In accordance with some embodiments of the present disclosure, a thickness of the upper protective portion is greater than a thickness of the lower protective portion, and the thickness of the lower protective portion is greater than a thickness of the intermediate protective portion.

In accordance with some embodiments of the present disclosure, during removal of the lower protective portion, each of the upper protective portion and the intermediate protective portion is partially removed.

In accordance with some embodiments of the present disclosure, after formation of the protective feature and before formation of the second dielectric layer, the method for manufacturing the semiconductor device further includes: conformally forming a first etch stop layer to cover the portions of the silicon-rich oxide layer and the protective feature; conformally forming a second etch stop layer to cover the first etch stop layer, the second etch stop layer and the first etch stop layer being made of different materials; forming a first oxide layer on the second etch stop layer opposite to the first etch stop layer; forming a second oxide layer on the first oxide layer opposite to the second etch stop layer, the second oxide layer and the first oxide layer being made of different materials; and removing the second oxide layer, a portion of the first oxide layer, a portion of the second etch stop layer, and a portion of the first etch stop layer.

In accordance with some embodiments of the present disclosure, a method for manufacturing a semiconductor device includes: forming a metallization layer over a substrate, the metallization layer including a first dielectric layer, and two metal lines disposed in the first dielectric layer and spaced apart from one another, the metallization layer having a first region and a second region, one of the two metal lines being disposed in the first region and the other one of the two metal lines being disposed in the second region; forming a memory element disposed over and electrically connected to the one of the two metal lines; forming a cap to laterally cover the memory element; forming a protective feature on the cap so as to cover a top surface of the memory element; forming a second dielectric layer on the protective feature and the cap opposite to the first dielectric layer; and forming a first contact via to penetrate the second dielectric layer and to terminate at the protective feature, so that the first contact via is electrically connected to the memory element through the protective feature.

In accordance with some embodiments of the present disclosure, after formation of the second dielectric layer and before formation of the first contact via, the method for manufacturing the semiconductor device further includes: forming an interconnect structure in the second dielectric layer and over the second region, the interconnect structure including a contact via disposed on the other one of the two metal lines and a metal line disposed on the contact via of the interconnect structure opposite to the other one of the two metal lines, wherein during formation of the first contact via, a second contact via is formed on and connected to the metal line of the interconnect structure.

In accordance with some embodiments of the present disclosure, the protective feature is selectively formed by chemical vapor deposition.

In accordance with some embodiments of the present disclosure, the protective feature is formed to have a curved top surface and a curved bottom surface connected to the curved top surface.

In accordance with some embodiments of the present disclosure, a semiconductor device includes a substrate, a metallization layer, a memory element, a cap, a protective feature, a second dielectric layer, and a contact via. The metallization layer is disposed over the substrate, and includes a first dielectric layer and a metal line disposed in the first dielectric layer. The memory element is disposed over and electrically connected to the metal line. The cap laterally covers the memory element. The protective feature is disposed on the cap and covers a top surface of the memory element. The second dielectric layer is disposed on the cap and the protective feature opposite to the first dielectric layer. The contact via penetrates the second dielectric layer and is disposed on the protective feature. The contact via is electrically connected to the memory element through the protective feature.

In accordance with some embodiments of the present disclosure, the protective feature includes tungsten, cobalt, titanium, titanium nitride, titanium silicide, or combinations thereof.

In accordance with some embodiments of the present disclosure, the protective feature is disposed to laterally cover the cap.

In accordance with some embodiments of the present disclosure, the protective feature includes an upper portion covering the top surface of the memory element, and a side portion extending downwardly from the upper portion to laterally cover the cap. A thickness of the upper portion is greater than a thickness of the side portion.

In accordance with some embodiments of the present disclosure, a ratio of a surface area of the upper portion of the protective feature to a surface area of the top surface of the memory element ranges from about 100% to about 250%.

In accordance with some embodiments of the present disclosure, the memory element includes a bottom electrode, a magnetic tunneling junction, and a top electrode. The bottom electrode is disposed over the metal line. The magnetic tunneling junction is disposed on the bottom electrode opposite to the metal line. The top electrode is disposed between the magnetic tunneling junction and the upper portion of the protective feature. A ratio of the thickness of the upper portion of the protective feature to a thickness of the bottom electrode ranges from about 33% to about 250%.

In accordance with some embodiments of the present disclosure, the protective feature is disposed to cover the top surface of the memory element and a portion of a top surface of the cap.

In accordance with some embodiments of the present disclosure, the protective feature includes a center portion covering the top surface of the memory element, and a side portion covering the portion of the top surface of the cap. A thickness of the center portion is greater than a thickness of the side portion.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a metallization layer over a substrate, the metallization layer including a first dielectric layer and a metal line disposed in the first dielectric layer;
forming a memory element disposed over and electrically connected to the metal line;
forming a cap to laterally cover the memory element;
forming a protective feature on the cap so as to cover a top surface of the memory element;
forming a second dielectric layer on the protective feature and the cap opposite to the first dielectric layer; and
forming a contact via to penetrate the second dielectric layer and to terminate at the protective feature, so that the contact via is electrically connected to the memory element through the protective feature.

2. The method as claimed in claim 1, further comprising, after formation of the metallization layer and before formation of the memory element,
forming a silicon-rich oxide layer on the first dielectric layer and the metal line, and
forming a bottom electrode via to penetrate the silicon-rich oxide layer and to terminate at the metal line,
wherein the cap is formed on the silicon-rich oxide layer, and laterally covers a portion of a sidewall of the bottom electrode via exposed from the silicon-rich oxide layer.

3. The method as claimed in claim 2, wherein formation of the cap includes:
forming a cap layer to cover the silicon-rich oxide layer, the portion of the sidewall of the bottom electrode via, and the memory element, the cap layer including a plurality of horizontal portions and a plurality of vertical portions, the plurality of horizontal portions being formed on the silicon-rich oxide layer and the top surface of the memory element, each of the plurality of vertical portions connecting one of the plurality of horizontal portions disposed on the top surface of the memory element and an adjacent one of the plurality of horizontal portions aside the memory element, and being formed to cover the portion of the sidewall of the bottom electrode via and a sidewall of the memory element; and
removing the plurality of horizontal portions so as to expose the top surface of the memory element and portions of the silicon-rich oxide layer.

4. The method as claimed in claim 3, wherein the protective feature includes an upper protective portion and an intermediate protective portion connected to the upper protective portion, and formation of the protective feature includes:
forming a protective layer including the upper protective portion, the intermediate protective portion, and a lower protective portion, the upper protective portion covering the top surface of the memory element and a top surface of the cap, the lower protective portion covering the portions of the silicon-rich oxide layer, the intermediate protective portion being connected to the upper protective portion and the lower protective portion, and laterally covering the cap; and
removing the lower protective portion so as to expose the portions of the silicon-rich oxide layer.

5. The method as claimed in claim 4, wherein the protective layer is formed by one of chemical vapor deposition and physical vapor deposition.

6. The method as claimed in claim 4, wherein a thickness of the upper protective portion is greater than a thickness of the lower protective portion, and the thickness of the lower protective portion is greater than a thickness of the intermediate protective portion.

7. The method as claimed in claim 4, wherein during removal of the lower protective portion, each of the upper protective portion and the intermediate protective portion is partially removed.

8. The method as claimed in claim 4, further comprising, after formation of the protective feature and before formation of the second dielectric layer,
conformally forming a first etch stop layer to cover the portions of the silicon-rich oxide layer and the protective feature;
conformally forming a second etch stop layer to cover the first etch stop layer, the second etch stop layer and the first etch stop layer being made of different materials;
forming a first oxide layer on the second etch stop layer opposite to the first etch stop layer;
forming a second oxide layer on the first oxide layer opposite to the second etch stop layer, the second oxide layer and the first oxide layer being made of different materials; and
removing the second oxide layer, a portion of the first oxide layer, a portion of the second etch stop layer, and a portion of the first etch stop layer.

9. A method for manufacturing a semiconductor device, comprising:
forming a metallization layer over a substrate, the metallization layer including a first dielectric layer, and two metal lines disposed in the first dielectric layer and spaced apart from one another, the metallization layer having a first region and a second region, one of the two metal lines being disposed in the first region and the other one of the two metal lines being disposed in the second region;
forming a memory element disposed over and electrically connected to the one of the two metal lines;
forming a cap to laterally cover the memory element;
forming a protective feature on the cap so as to cover a top surface of the memory element;
forming a second dielectric layer on the protective feature and the cap opposite to the first dielectric layer; and
forming a first contact via to penetrate the second dielectric layer and to terminate at the protective feature, so that the first contact via is electrically connected to the memory element through the protective feature.

10. The method as claimed in claim 9, further comprising, after formation of the second dielectric layer and before formation of the first contact via, forming an interconnect structure in the second dielectric layer and over the second region, the interconnect structure including a contact via disposed on the other one of the two metal lines and a metal line disposed on the contact via of the interconnect structure opposite to the other one of the two metal lines, wherein during formation of the first contact via, a second contact via is formed on and connected to the metal line of the interconnect structure.

11. The method as claimed in claim 9, wherein the protective feature is selectively formed by chemical vapor deposition.

12. The method as claimed in claim 9, wherein the protective feature is formed to have a curved top surface and a curved bottom surface connected to the curved top surface.

13. A semiconductor device, comprising:
a substrate;
a metallization layer disposed over the substrate, and including a first dielectric layer and a metal line disposed in the first dielectric layer;
a memory element disposed over and electrically connected to the metal line;
a cap laterally covering the memory element;
a protective feature disposed on the cap and covering a top surface of the memory element;
a second dielectric layer disposed on the cap and the protective feature opposite to the first dielectric layer; and
a contact via penetrating the second dielectric layer and disposed on the protective feature, the contact via being electrically connected to the memory element through the protective feature.

14. The semiconductor device as claimed in claim 13, wherein the protective feature includes tungsten, cobalt, titanium, titanium nitride, titanium silicide, or combinations thereof.

15. The semiconductor device as claimed in claim 13, wherein the protective feature is disposed to laterally cover the cap.

16. The semiconductor device as claimed in claim 15, wherein the protective feature includes an upper portion covering the top surface of the memory element, and a side portion extending downwardly from the upper portion to laterally cover the cap, a thickness of the upper portion being greater than a thickness of the side portion.

17. The semiconductor device as claimed in claim 16, wherein a ratio of a surface area of the upper portion of the protective feature to a surface area of the top surface of the memory element ranges from 100% to 250%.

18. The semiconductor device as claimed in claim 16, wherein the memory element includes:
a bottom electrode disposed over the metal line;
a magnetic tunneling junction disposed on the bottom electrode opposite to the metal line; and
a top electrode disposed between the magnetic tunneling junction and the upper portion of the protective feature,
a ratio of the thickness of the upper portion of the protective feature to a thickness of the bottom electrode ranging from 33% to 250%.

19. The semiconductor device as claimed in claim 13, wherein the protective feature is disposed to cover the top surface of the memory element and a portion of a top surface of the cap.

20. The semiconductor device as claimed in claim 19, wherein the protective feature includes a center portion covering the top surface of the memory element, and a side portion covering the portion of the top surface of the cap, a thickness of the center portion being greater than a thickness of the side portion.
